(19) United States
(12) Patent Application Publication
(10) Pub. No.: US 2026/0173327 A1
(43) Pub. Date: Jun. 18, 2026

(54) SYSTEMS AND METHODS FOR IMPROVING UNIFORMITY OF PROCESSING DEVICE PERFORMANCE ON COMPUTING BOARDS

(71) Applicant: Advanced Micro Devices, Inc., Santa Clara, CA (US)

(72) Inventors: Sriram Sundaram, Austin, TX (US); Joshua Friedrich, Austin, TX (US)

(73) Assignee: Advanced Micro Devices, Inc., Santa Clara, CA (US)

(21) Appl. No.: 18/979,736

(22) Filed: Dec. 13, 2024

(51) Int. Cl. H05K 7/20

(52) U.S. Cl. CPC H05K 7/20836; H05K 7/20718; H05K 7/20763

(57) ABSTRACT

A system for improving uniformity of processing device performance on computing boards can include a server that includes a computing board and a cooling system, where the computing board includes a circuit board and first and second processing devices attached to the circuit board, where each of the first processing devices satisfies first performance criteria at a particular temperature and each of the second processing devices satisfies second performance criteria at the particular temperature, and where the cooling system is configured to move a cooling substance from an intake port to a first region in which the first processing devices are attached to the circuit board, from the first region to a second region in which at least a subset of the second processing devices are attached to the circuit board, and from the second region to an exhaust port.

### BACKGROUND

Computing devices typically have one or more processing devices, such as central processing units (CPUs) and/or graphics processing units (GPUs). While some computing devices have a small number of processing devices, other computing devices (e.g., some servers) have a large number of processing devices attached to one or more computing boards. A computing device can be equipped with a cooling system that cools the processing devices within the computing device, often via moving air or water around the processing devices. Effectively cooling a processing device can improve the efficiency, performance, and longevity of the processing device.

### BRIEF DESCRIPTION OF THE FIGURES

The accompanying drawings illustrate a number of example implementations and are a part of the specification. Together with the following description, these drawings demonstrate and explain various principles of the present disclosure.

FIG. 1 is a block diagram of an example computer system.

FIG. 2 is a flow diagram of an example method for improving uniformity of processing device performance on computing boards.

FIG. 3 is a block diagram of an example computing board.

FIG. 4 is a block diagram of components of an example server, including a computing board and a cooling system.

FIG. 5 is an illustration of an example server rack shelf.

FIG. 6 is a block diagram of an example server rack.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure describes systems and methods for improving uniformity of processing device performance on computing boards. In some cases, processing devices on a computing board can have different performance characteristics. In some configurations, a computing board can be constrained by the performance characteristics (e.g., processing speed and/or throughput) of the lowest performing processing device attached to the computing board. For example, processing devices such as GPUs are often assembled together with a circuit board and sold to customers in the form of a computing board (e.g., a Universal Base Board (UBB)) that includes multiple GPUs. In one example, a UBB can include eight GPUs. One arrangement of eight GPUs is two rows of four. In many cases, each UBB is air cooled and the direction of air flow is such that the front row of four GPUs is cooled by air received at the inlet temperature, but the back row ends up receiving air at higher temperature (since the air is heated by the front row GPUs before reaching the back row GPUs). In many cases, this caloric rise is around 10° C. Since leakage power increases exponentially with temperature and many computing boards operate all GPUs at the same power budget, this temperature discrepancy puts the back row GPUs at a performance disadvantage compared to front row GPUs.

Due to process technology and manufacturing variations, there is inherent variation in the performance each GPU can deliver under fixed power constraints and identical environmental conditions. The systems described herein can use an opportunistic GPU placement in UBBs to enhance the delivered performance at the UBB level by placing the relatively slower GPUs in the front (lower temperature) row and faster GPUs in the back (higher temperature) row, resulting in more even (e.g., uniform) GPU performance across the UBB.

Many data center GPU applications can be characterized by bulk synchronous behaviors. For example, machine learning (ML) and/or artificial intelligence (AI) workloads may involve synchronous processing of large quantities of data. Large problems are subdivided into smaller parts and issued to be processed in parallel by several GPUs and then the results combined. In this class of applications, the net throughput or performance is limited by the slowest individual GPU. Thus, variation in GPU performance can mean that minimum performant GPU determines the performance at the cluster level (e.g., a UBB, a set of UBBs, a set of servers, etc.). In these cases, reducing variability in GPU performance can improve overall throughput.

For ease of understanding, the foregoing paragraphs describe a specific example of a UBB with GPUs organized in two rows of four. One of ordinary skill in the art will appreciate that the above-described techniques for improving the uniformity of performance of processing devices on a computing board are applicable to any type of computing board having any type of processing devices arranged in any suitable configuration.

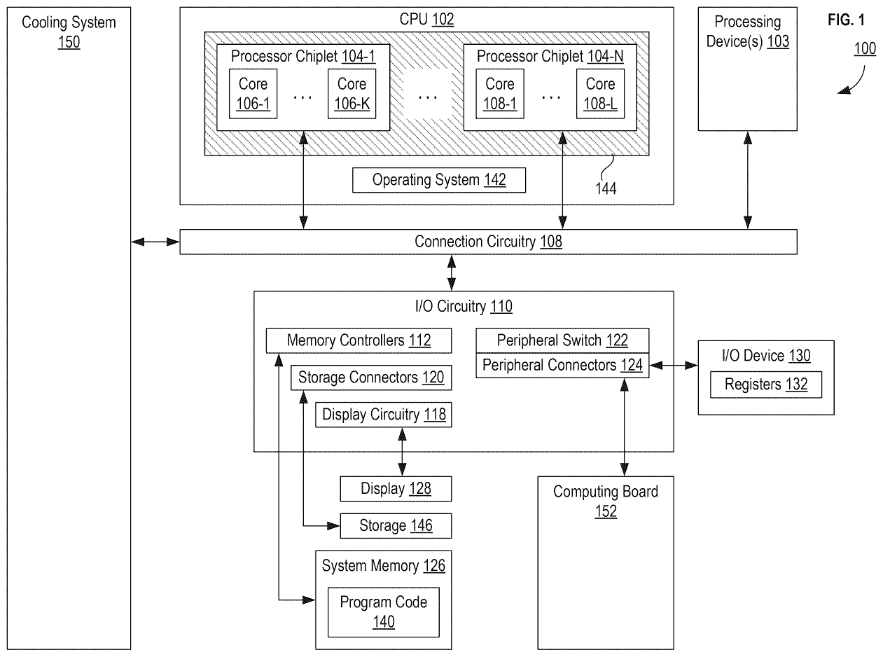

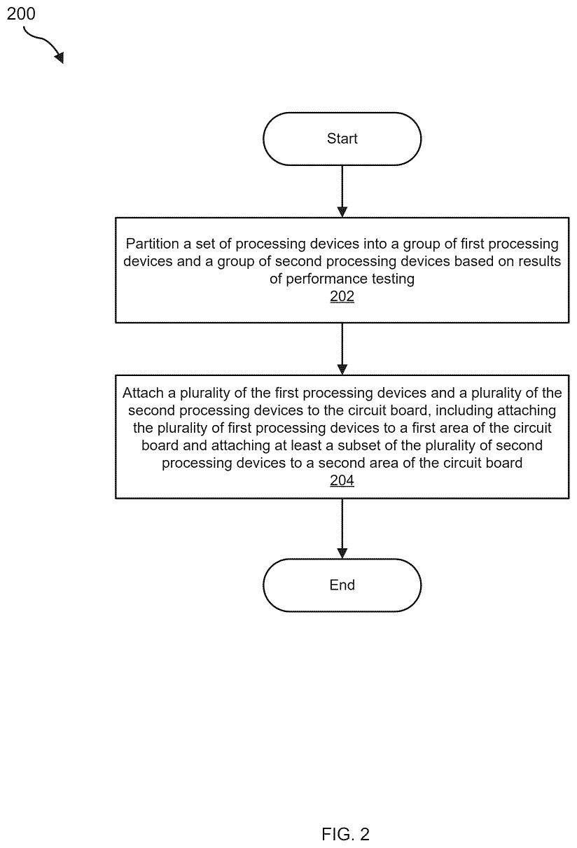

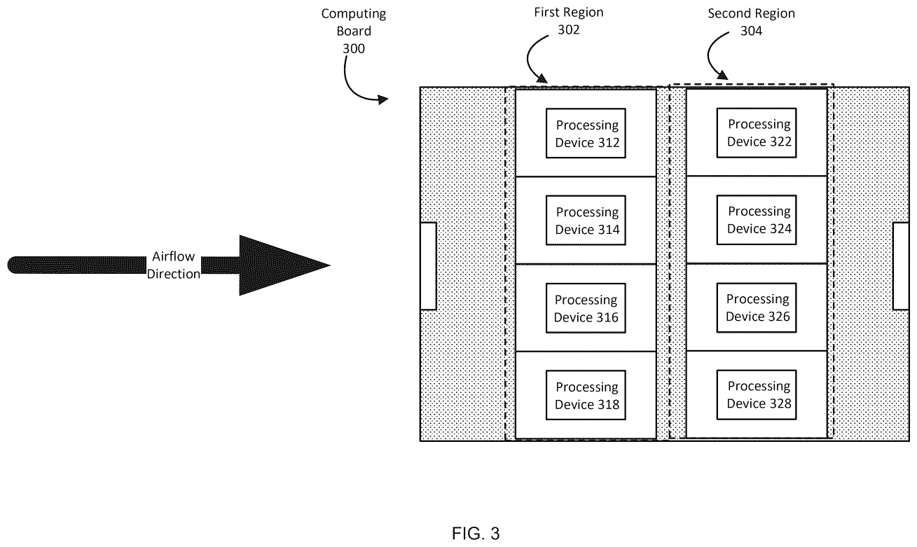

This disclosure provides, with reference to FIG. 1, detailed descriptions of example devices and systems for improving uniformity of processing device performance on computing boards. Detailed descriptions of corresponding methods for improving uniformity of processing device performance on computing boards are provided in connection with FIG. 2. Detailed descriptions of example computing boards, servers, and server racks are provided in connection with FIGS. 3-6.

In some aspects, the techniques described herein relate to a system including: a server including a computing board and a cooling system, wherein the computing board includes a circuit board and a plurality of first processing devices and a plurality of second processing devices attached to the circuit board, wherein each of the first processing devices satisfies one or more first performance criteria at a particular temperature and each of the second processing devices satisfies one or more second performance criteria at the particular temperature; and wherein the cooling system configured to move a cooling substance from an intake port to a first region in which the first processing devices are attached to the circuit board, from the first region to a second region in which at least a subset of the second processing devices are attached to the circuit board, and from the second region to an exhaust port.

In some aspects, the techniques described herein relate to a system, wherein a first performance level satisfying the first performance criteria is lower than a second performance level satisfying the second performance criteria, and the first performance level does not satisfy the second performance criteria.

In some aspects, the techniques described herein relate to a system, wherein: the cooling system is operable to cool the first region to a first temperature and the second region to a second temperature higher than the first temperature; the plurality of first processing devices are configured to perform at a first performance level at the first temperature; the plurality of second processing devices are configured to perform at a second performance level at the second temperature; and the first performance level is within a specified range of the second performance level.

In some aspects, the techniques described herein relate to a system, wherein the specified range is 10%, 8%, 6%, 5%, 4%, 3%, or 2%.

In some aspects, the techniques described herein relate to a system, wherein the each of the first processing devices and each of the second processing devices includes a graphics processing unit (GPU).

In some aspects, the techniques described herein relate to a system, wherein the server is a first server affixed within a server rack including a plurality of second servers.

In some aspects, the techniques described herein relate to a system, wherein the plurality of first processing devices and the plurality of second processing devices include a combined total of eight processing devices arranged on the circuit board in two rows each including four of the eight processing devices, such that a first row of the two rows is within the first region and a second row of the two rows is within the second region.

In some aspects, the techniques described herein relate to a system, wherein the cooling substance includes ambient air.

In some aspects, the techniques described herein relate to a system, wherein the cooling substance includes liquid coolant.

In some aspects, the techniques described herein relate to a system, wherein the computing board satisfies a universal baseboard (UBB) design specification.

In some aspects, the techniques described herein relate to a system, wherein the computing board is configured to provide approximately equal amounts of electrical power to each processing device of the first and second pluralities of processing devices.

In some aspects, the techniques described herein relate to a method of assembling a computing board, the method including: partitioning a set of processing devices into a group of first processing devices and a group of second processing devices based on results of performance testing of the set of processing devices, wherein each of the first processing devices satisfies one or more first performance criteria at a particular temperature and each of the second processing devices satisfies one or more second performance criteria at the particular temperature; and attaching a plurality of the first processing devices and a plurality of the second processing devices to a circuit board, wherein the attaching includes attaching the plurality of first processing devices to a first area of the circuit board and attaching at least a subset of the plurality of second processing devices to a second area of the circuit board, wherein the first area of the circuit board is configured to be disposed upstream from the second area of the circuit board along a flow path of a cooling substance of a cooling system.

In some aspects, the techniques described herein relate to a method, further including performing the performance testing of the set of processing devices, including: detecting that fewer than a specified percentage of the set of processing devices satisfy the one or more second performance criteria; and updating the one or more second performance criteria such that at least the specified percentage of the plurality of processing devices satisfy the updated one or more second performance criteria.

In some aspects, the techniques described herein relate to a method, further including performing the performance testing of the set of processing devices, including: for each processing device in the set of processing devices, monitoring a performance of the processing device and a temperature of the processing device while performing at least one processing test.

In some aspects, the techniques described herein relate to a method, further including performing the performance testing of the plurality of processing devices, including: for each processing device in the set of processing devices, performing an end-to-end performance test of the processing device.

In some aspects, the techniques described herein relate to a method, wherein: the cooling system is operable to cool the first area to a first temperature and the second area to a second temperature higher than the first temperature; the plurality of first processing devices are configured to perform at a first performance level at the first temperature; the plurality of second processing devices are configured to perform at a second performance level at the second temperature; and the first performance level is within a specified range of the second performance level.

In some aspects, the techniques described herein relate to a method, wherein the specified range is 10%, 8%, 6%, 5%, 4%, 3%, or 2%.

In some aspects, the techniques described herein relate to a method, wherein the each of the first processing devices and each of the second processing devices includes a GPU.

In some aspects, the techniques described herein relate to a computing device including: a circuit board; a plurality of first processing devices, wherein each of the first processing devices is configured to satisfy one or more first performance criteria at a particular temperature; and a plurality of second processing devices, wherein each of the second processing devices is configured to satisfy one or more second performance criteria at the particular temperature; wherein the first processing devices are attached to a first area of the circuit board, at least a subset of the second processing devices are attached to a second area of the circuit board, and the first area of the circuit board is configured to be disposed upstream from the second area of the circuit board along a flow path of a cooling substance of a cooling system.

In some aspects, the techniques described herein relate to a computing device, further including the cooling system, wherein the cooling system is configured to move the cooling substance along the flow path from an intake port to the first area of the circuit board, from the first area to the second area of the circuit board, and from the second area to an exhaust port.

FIG. 1 illustrates one exemplary implementation of a computer system 100 configured to implement the techniques described herein, although others are possible. It should be appreciated that FIG. 1 is intended neither to be a depiction of necessary components for a computer system 100 to operate in accordance with the principles described herein, nor a comprehensive depiction.

Computer system 100 can be, for example, a server, such as an application server, a database server, and/or any other type of server. Computer system 100 can comprise at least one central processing unit (CPU) 102, one or more processing devices 103 (e.g., graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc.), connection circuitry 108, I/O circuitry 110, system memory 126, at least one I/O device 130, storage 146 (e.g., computer-readable storage media), and/or at least one display 128. In some examples, the CPU 102, processing device(s) 103, connection circuitry 108, and I/O circuitry 110, are coupled to (e.g., mounted on) a printed circuit board.

In some examples, computer system 100 includes a computing board 152. In one example, computing board 152 and/or other components of computer system 100 can be cooled by a cooling system 150. The term “computing board,” as used herein, can generally refer to any assembly of computing components that includes one or more processing devices affixed to a base (e.g., substrate) including but not limited to a printed circuit board. In some examples, a computing board can comply with a universal baseboard (UBB) design specification (e.g., a standards specification for a UBB, such as the Open Accelerator Infrastructure (OAI) Universal Baseboard (UBB) Base Specification) and/or an expansion module design specification (e.g., a standards specification for an expansion module, such as the OAI Expansion Module (EXP) Base Specification). The term UBB, as used herein, can generally refer to any computing board configured to be used within a server.

CPU 102 enables processing of data and execution of instructions. The data and instructions can be stored on system memory 126, storage 146, and/or internal memory (not shown) of the CPU 102. In some examples, the CPU 102 includes one or more processor chiplets 104-1 ... 104-N, which can be disposed on or over a package substrate 144. In some examples, the processor chiplets can communicate with each other via interconnects routed through or on the package substrate 144 (e.g., through an interposer layer disposed between the package substrate 144 and the processor chiplets). In some examples, each processor chiplet includes one or more cores (106, 108). Different processor chiplets can have the same or different numbers of cores (106, 108). In the example of FIG. 1, processor chiplet 104-1 has K cores 106-1 . . . 106-K, and processor chiplet 104-N has L cores (108-1, 108-2, . . . 108-L). The cores within an individual processor chiplet (e.g., cores 106-1 . . . 106-K) can be homogeneous or heterogeneous. Likewise, the cores on different processor chiplets (e.g., cores 106-1 and 108-1) can be homogeneous or heterogeneous.

In the example of FIG. 1, the CPU 102 is configured to execute instructions of an operating system 142 and/or instructions (e.g., program code 140) of one or more applications. In some examples, the functionality of the program code can be implemented by one or more processing devices 103, one or more CPUs 102, one or more processor chiplets of a CPU 102, and/or one or more cores of a processor chiplet.

The data and instructions stored on any of the computer-readable storage media (e.g., system memory 126, storage 146, internal or external caches of the CPU 102, etc.) can comprise computer-executable instructions implementing any suitable functionality.

In some examples, connection circuitry 108 communicatively couples CPUs 102 with each other, with processing device(s) 103, and/or with external caches (e.g., level-2 (L2) cache, level-3 (L3) cache, etc.). Additionally or alternatively, the connection circuitry 108 can communicatively couple the CPUs 102 with I/O circuitry 110, which communicatively couples system memory, storage devices, and peripheral devices to each other and (via the connection circuitry 108) to the CPUs 102. The connection circuitry can couple the CPUs 102, external caches, and I/O circuitry 110 using any suitable network topology (e.g., a front-side bus, a back-side bus, etc.), and the coupled components can send and receive messages via the connection circuitry using any suitable communication protocol. In some examples, portions of the connection circuitry 108 can be integrated into the CPU(s) 102 and/or processing device(s) 103.

In some examples, I/O circuitry 110 includes one or more memory controllers 112, one or more storage connectors 120, display circuitry 118, one or more peripheral connectors 124, and a peripheral switch 122. The memory controller(s) 112 can be configured to control the flow of data to and from the system memory 126. The storage connector(s) 120 can be configured to control the flow of data to and from the storage 146. The display circuitry 118 can be configured to send visual data (e.g., user interface data, image data, video data, etc.) to the display 128, which can be configured to display the visual data. In some examples, the display circuitry 118 can also be configured to receive data representing user input from the display 128 (e.g., in cases where the display 128 includes a touchscreen). In some examples, portions of the I/O circuitry 110 can be integrated into a motherboard and/or motherboard chipset (e.g., I/O circuitry 110) of the computer system 100.

Each of the peripheral connectors 124 can be configured to physically connect and communicatively couple the I/O circuitry 110 to a peripheral device. Any suitable type of peripheral device can be connected to a peripheral connector 124 including, without limitation, an I/O device 130 (e.g., an input device, output device, or input/output device), etc. Some non-limiting examples of an input device can include a mouse, keyboard, scanner, video game controller, microphone, webcam, etc. Some non-limiting examples of an output device can include a display, printer, speakers, headphones, earbuds, etc. Some non-limiting examples of an input/output device can include a storage device (e.g., disk drive, solid-state drive, universal serial bus (USB) flash drive, memory card, tape drive, etc.), a networking device (e.g., modem, router, gateway, network adapter, access point, etc.), etc. A networking adapter can be any suitable hardware and/or software to enable the computer system 100 to communicate via wires and/or wirelessly with any other suitable computing system over any suitable computing network. The computing network can include wireless access points, switches, routers, gateways, and/or other networking equipment as well as any suitable wired and/or wireless communication medium or media for exchanging data between two or more computers, including the Internet. Optionally, an I/O device can include one or more registers 132. In some examples, the I/O circuitry 110 can control the operation of an I/O device 130 by writing suitable data to one or more of the I/O device's registers, and/or can monitor the status of an I/O device 130 by reading the contents of one or more of the I/O device's registers.

The peripheral switch 122 can be configured to switch packets sent to or from the peripheral devices. Any suitable type of peripheral connector(s) 124 and peripheral switch 122 can be used including, without limitation, universal serial bus (e.g., USB-A, USB-B, USB-C, USB-3.0, etc.), Ethernet, DisplayPort, high-definition multimedia interface (HDMI), peripheral component interconnect (PCI), peripheral component interconnect eXtended (PCI-X), peripheral component interconnect express (PCIe), accelerated graphics port (AGP), etc.

As described above computer system 100 can have one or more components and peripherals, including input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computing device can receive input information through speech recognition or in other audible format.

In some examples, computer system 100 can be include a UBB with GPUs placed such that lower-performing GPUs are more effectively cooled by cooling system 150 than other GPUs, resulting in less variable GPU performance within computing system 100.

FIG. 2 is a flow diagram of an example method 200 for improving uniformity of processing device performance on computing boards. The method 200 can be performed, for example, by a manufacturer or assembler of computing boards, using manual and/or automated manufacturing/assembly techniques. As illustrated in FIG. 2, at step 202, manufacturers can partition a set of processing devices into two or more groups (e.g., a group of first processing devices and a group of second processing devices) based on results of performance testing. Such performance testing can include end-to-end testing of the processing devices, for example by performing processing tests such as providing the processing devices with a set of data to process while monitoring the temperature of the processing devices, the time it takes each processing device to process the set of data, and/or other attributes of the performance of each processing device. In one example, the systems described herein can assess part-specific leakage power, dynamic power, and/or voltage frequency curves to assess the performance grade of processing devices under identical power and environmental constraints. The results of such performance testing can include any suitable performance data or ratings, for example, a performance score assigned to each of the processing devices.

In some examples, one or more performance criteria can be used to partition the processing devices into the first group of comparatively lower-performing devices and the second group of comparatively higher-performing devices. In some examples, these performance criteria can be calibrated such that specified ratios (e.g., proportions) of the processing devices are partitioned into the groups, e.g., 50% of the devices into each group, or 40% of the devices into the first group and 60% into the second group, or 30% of the devices into the first group and 70% into the second group, etc.

In some examples, the performance criteria can be altered to ensure that the specified ratios are maintained. It is advantageous to locate the lower-performing devices closer to the intake for the cooling system but the higher-performing devices can be located in positions closer to or farther from the intake. Thus, in some examples, the performance criteria are set and the ratios are maintained such that no more than 50% of the devices are categorized as lower performing. In some examples, the ratios may be set such that somewhat fewer devices are categorized as lower-performing (e.g., 60% higher-performing devices to 40% lower-performing devices), to create a margin of safety in case a batch of devices is outside the typical level of performance variation.

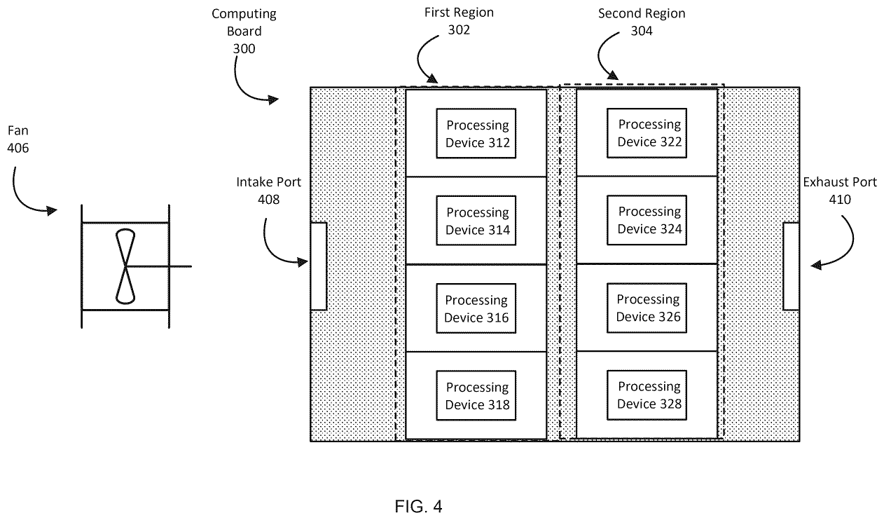

In some examples, a first area of the circuit board can include N_{A1} positions (e.g., sockets) at which N_{A1} processing devices can be attached to the circuit board, and a second area of the circuit board can include N_{A2} positions (e.g., sockets) at which N_{A2} processing devices can be attached to the circuit board, where each of N_{A1} and N_{A2} is any suitable positive integer. The first area of the circuit board can be “closer” than the second area to the intake for a cooling system (e.g., the first area can be upstream from the second area along a flow path of the cooling substance of the cooling system), and the second area of the circuit board can be “farther” than the first area from the intake for the cooling system (e.g., the second area can be downstream from the first area along a flow path of the cooling substance of the cooling system). Such areas of the circuit board are described in greater detail in connection with FIGS. 3 and 4.

At step 204, a number N_{G1} of first processing devices and a number N_{G2} of the second processing devices can be attached (e.g., affixed) to the circuit board, where N_{G1}+N_{G2}=N_{A1}+N_{A2}. In some examples, the N_{G1} first processing devices are attached to the first area of the circuit board, and N_{G1} is less than or equal to N_{A1}. In some examples, at least a subset of the N_{G2} second processing devices are attached to the second area of the circuit board, and N_{G2} is greater than or equal to N_{A2}. In some examples, one or more of the N_{G2} second processing devices are attached to the first area of the circuit board. Any suitable technique can be used to attach the processing devices to the circuit board. As discussed above, the attachment of one or more second processing devices to the first area of the circuit board can be advantageous if more than 50% of the processing devices are partitioned into the second group of higher-performing processing devices.

FIG. 3 is a block diagram of an example computing board 300. As illustrated in FIG. 3, computing board 300 can have a first region 302 that receives airflow first before a second region 304. In one example, processing devices 312, 314, 316, and/or 318 can be affixed to computing board 300 in first region 302 while processing devices 322, 324, 326, and/or 328 can be affixed to computing board 300 in second region 304. In one example, processing devices 322, 324, 326, and/or 328 can all be higher-performing processing devices while processing devices 312, 314, 316, and/or 318 can be a combination of higher-performing and lower-performing processing devices. For example, processing devices 312, 314, 316, and/or 318 can all be lower-performing processing devices while processing devices 322, 324, 326, and/or 328 can all be higher-performing processing devices. In another example, processing devices 312, 318, 322, 324, 326, and/or 328 can all be higher-performing processing devices while only processing devices 314 and/or 316 can be lower-performing processing devices.

In some examples, computing board 300 can be configured to provide approximately equal amounts (e.g., substantially equal amounts) of electrical power to each of processing devices 312, 314, 316, 318, 322, 324, 326, and/or 328.

In some examples, as is illustrated in FIG. 4, the systems described herein can include and/or be coupled to a structure that includes a cooling system. For example, a fan 406 can circulate cooled air into computing board 300 via an intake port 408. The cooled air can first pass through first region 302, where the cooled air is heated by processing devices 312, 314, 316, and/or 318, before passing through second region 304 and exiting via exhaust port 410.

Although illustrated as an air-cooling system with a fan, the systems described herein can include and/or be coupled to a cooling system that uses any type of coolant, including a liquid cooling system. The term “cooling system,” as used herein, can generally refer to any system that circulates a cooling substance through a computing board.

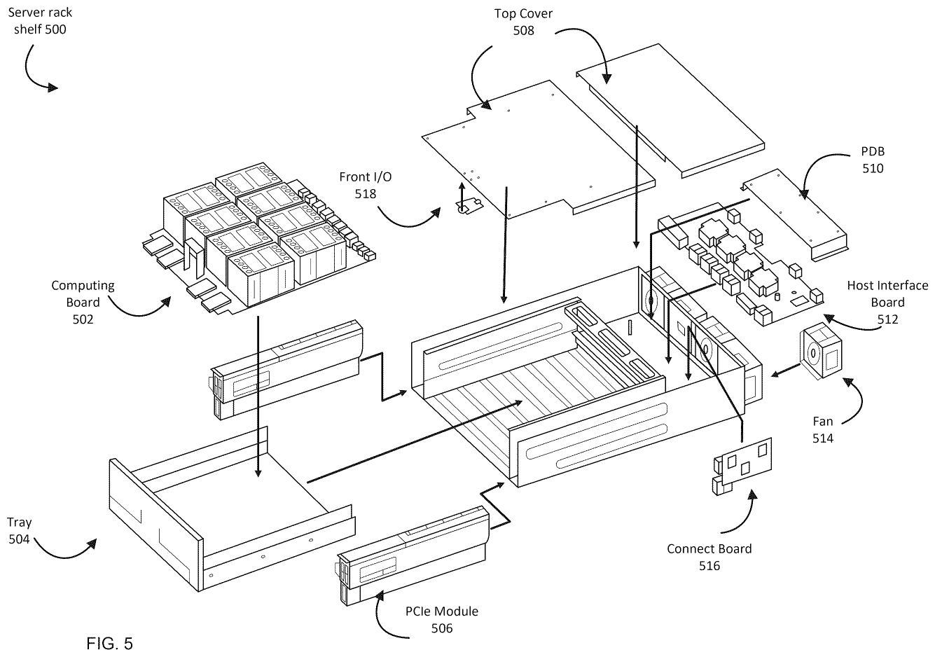

In one example, a server can be configured with a cooling system that cools one or more computing boards within the server. For example, as illustrated in FIG. 5, a server rack shelf 500 can include a computing board 502 (e.g., computing board 300) that sits in a tray 504 alongside one or more peripheral component interconnect express (PCIe) modules 506, a connect board 516, a host interface board 512, and/or a power distribution board (PDB) 510. In this example, these components can be cooled by a fan 514 affixed to tray 504. In some examples, tray 504 can also be affixed to a top cover 508 that includes a front input/output 518. In some examples, computing board 502 can be compliant with specifications for the open accelerator infrastructure (OAI) UBB and/or OAI expansion module.

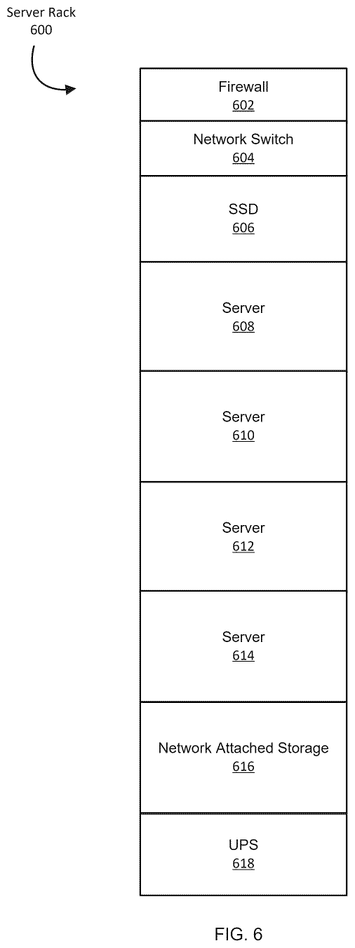

In some examples, the systems described herein can be housed in and/or affixed to a server rack. For example, as illustrated in FIG. 6, a server rack 600 can include a firewall 602, a network switch 604, a solid-state drive (SSD) 606, one or more servers 608, 610, 612, and/or 614, network attached storage 616, and/or an uninterruptable power supply (UPS) 618. Although illustrated with four servers, server rack 600 can include varying numbers of servers such as six, ten, twelve, fifteen, twenty-four, forty-two, forty-eight, and/or any other number of servers. In some examples, multiple servers in server rack 600 can include computing boards with processing device configurations as described above. In one example, each of servers 608, 610, 612, and 614 can include a computing board assembled as described in connection with any of FIGS. 2-5. In some examples, all servers within server rack 600 can include computing boards assembled as described herein, while in other examples, only some servers can include such computing boards while others can include computing boards assembled in other ways.

As described above, an advantage of the above-described GPU pairing-placement in UBBs is that it combines two known sources of performance variation in GPUs under fixed power constraints such that overall performance distribution across GPUs is tightened and the deficit between the slowest GPU and average GPU is minimized. This is extremely valuable in data center GPU and the bulk synchronous applications they are typically used to solve, where the overall performance of large clusters is limited by slowest GPU module. Thus, improving the performance of the slowest GPU through the systems described herein directly improves the performance of the cluster.

Techniques operating according to the principles described herein can be implemented in any suitable manner. While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered as non-limiting examples since many other architectures can be implemented to achieve the same functionality.

Included in the discussion above are flowcharts showing steps and acts of processes that regulate the voltage of a signal. The processing and decision blocks of the flowcharts above represent steps and acts that can be included in algorithms that carry out these processes. Algorithms derived from these processes (or steps thereof) can be implemented as software integrated with and directing the operation of one or more single-or multi-purpose processors (e.g., central processing units (CPUs), graphics processing units (GPUs), tensor processing units (TPUs), hardware accelerators, etc.), can be implemented as functionally-equivalent circuits such as a Digital Signal Processing (DSP) circuit, Field Programmable Gate Array (FPGA), or an Application-Specific Integrated Circuit (ASIC), or can be implemented in any other suitable manner. It should be appreciated that the flowchart(s) included herein do not depict the syntax or operation of any particular circuit or of any particular programming language or type of programming language. Rather, the flowchart(s) illustrate the functional information one of ordinary skill in the art can use to fabricate circuits or to implement computer software algorithms to perform the processing of a particular apparatus carrying out the types of techniques described herein. It should also be appreciated that, unless otherwise indicated herein, the particular sequence of steps and/or acts described in each flowchart is merely illustrative of the algorithms that can be implemented and can be varied in implementations and examples of the principles described herein.

Accordingly, in some examples, the techniques described herein can be embodied in computer-executable instructions implemented as software, including as application software, system software, firmware, middleware, embedded code, or any other suitable type of software. Such computer-executable instructions can be written using any of a number of suitable programming languages and/or programming or scripting tools, and also can be compiled as executable machine language code or intermediate code that is executed on a framework or virtual machine.

When techniques described herein are embodied as computer-executable instructions, these computer-executable instructions can be implemented in any suitable manner, including as a number of functional facilities, each providing one or more operations to complete execution of algorithms operating according to these techniques. A “functional facility,” however instantiated, is a structural component of a computer system that, when integrated with and executed by one or more computers, causes the one or more computers to perform a specific operational role. A functional facility can be a portion of or an entire software element. For example, a functional facility can be implemented as a function of a process, or as a discrete process, or as any other suitable unit of processing. If techniques described herein are implemented as multiple functional facilities, each functional facility can be implemented in its own way; all need not be implemented the same way. Additionally, these functional facilities can be executed in parallel and/or serially, as appropriate, and can pass information between one another using a shared memory on the computer(s) on which they are executing, using a message passing protocol, or in any other suitable way.

Generally, functional facilities include routines, programs, objects, components, data structures, etc. that perform particular tasks or implement particular abstract data types. Typically, the functionality of the functional facilities can be combined or distributed as desired in the systems in which they operate. In some implementations, one or more functional facilities carrying out techniques herein can together form a complete software package. These functional facilities can, in alternative examples, be adapted to interact with other, unrelated functional facilities and/or processes, to implement a software program application. In other implementations, the functional facilities can be adapted to interact with other functional facilities in such a way as form an operating system, including the Windows® operating system, available from the Microsoft® Corporation of Redmond, Washington. In other words, in some implementations, the functional facilities can be implemented alternatively as a portion of or outside of an operating system.

Some exemplary functional facilities have been described herein for carrying out one or more tasks. It should be appreciated, though, that the functional facilities and division of tasks described is merely illustrative of the type of functional facilities that can implement the exemplary techniques described herein, and that examples are not limited to being implemented in any specific number, division, or type of functional facilities. In some implementations, all functionality can be implemented in a single functional facility. It should also be appreciated that, in some implementations, some of the functional facilities described herein can be implemented together with or separately from others (i.e., as a single unit or separate units), or some of these functional facilities can be omitted.

Computer-executable instructions implementing the techniques described herein (when implemented as one or more functional facilities or in any other manner) can, in some examples, be encoded on one or more computer-readable media to provide functionality to the media. Computer-readable media include magnetic media such as a hard disk drive, optical media such as a Compact Disk (CD) or a Digital Versatile Disk (DVD), a persistent or non-persistent solid-state memory (e.g., Flash memory, Magnetic RAM, etc.), or any other suitable storage media. Such a computer-readable medium can be implemented in any suitable manner, including as system memory 126, and/or storage 146 of the computer system 100 of FIG. 1 or as a stand-alone, separate storage medium. As used herein, “computer-readable media” (also called “computer-readable storage media”) refers to tangible storage media. Tangible storage media are non-transitory and have at least one physical, structural component. In a “computer-readable medium,” as used herein, at least one physical, structural component has at least one physical property that can be altered in some way during a process of creating the medium with embedded information, a process of recording information thereon, or any other process of encoding the medium with information. For example, a magnetization state of a portion of a physical structure of a computer-readable medium can be altered during a recording process.

Further, some techniques described above comprise acts of storing information (e.g., data and/or instructions) in certain ways for use by these techniques. In some implementations of these techniques-such as implementations where the techniques are implemented as computer-executable instructions—the information can be encoded on a computer-readable storage media. Where specific structures are described herein as advantageous formats in which to store this information, these structures can be used to impart a physical organization of the information when encoded on the storage medium. These advantageous structures can then provide functionality to the storage medium by affecting operations of one or more processors interacting with the information; for example, by increasing the efficiency of computer operations performed by the processor(s).

In some, but not all, implementations in which the techniques can be embodied as computer-executable instructions, these instructions can be executed on one or more suitable computing device(s) operating in any suitable computer system, or one or more computing devices (or one or more processors of one or more computing devices) can be programmed to execute the computer-executable instructions. A computing device or processor can be programmed to execute instructions when the instructions are stored in a manner accessible to the computing device/processor, such as in a local memory (e.g., an on-chip cache or instruction register, a computer-readable storage medium accessible via a bus, a computer-readable storage medium accessible via one or more networks and accessible by the device/processor, etc.). Functional facilities that comprise these computer-executable instructions can be integrated with and direct the operation of a single multi-purpose programmable digital computer apparatus, a coordinated system of two or more multi-purpose computer apparatuses sharing processing power and jointly carrying out the techniques described herein, a single computer apparatus or coordinated system of computer apparatuses (co-located or geographically distributed) dedicated to executing the techniques described herein, one or more Field-Programmable Gate Arrays (FPGAs) for carrying out the techniques described herein, or any other suitable system.

Examples have been described where the techniques are implemented in circuitry and/or computer-executable instructions. It should be appreciated that some examples can be in the form of a method, of which at least one example has been provided. The acts performed as part of the method can be ordered in any suitable way. Accordingly, examples can be constructed in which acts are performed in an order different than illustrated, which can include performing some acts simultaneously, even though shown as sequential acts in illustrative examples.

Various aspects of the examples described above can be used alone, in combination, or in a variety of arrangements not specifically discussed in the examples described in the foregoing and is therefore not limited in its application to the details and arrangement of components set forth in the foregoing description or illustrated in the drawings. For example, aspects described in one example can be combined in any manner with aspects described in other examples.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The word “exemplary” is used herein to mean serving as an example, instance, or illustration. Any example, implementation, process, feature, etc. described herein as exemplary should therefore be understood to be an illustrative example and should not be understood to be a preferred or advantageous example unless otherwise indicated.

The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements can optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one example, to A only (optionally including elements other than B); in another example, to B only (optionally including elements other than A); in yet another example, to both A and B (optionally including other elements); etc.

Unless otherwise noted, the terms “connected to” and “coupled to” (and their derivatives), as used in the specification and claims, are to be construed as permitting both direct and indirect (i.e., via other elements or components) connection.

Unless otherwise noted, a first numeric value is “approximately” or “substantially” equal to a second numeric value if the first numeric value is within ±20%, ±10%, or ±5% of the second numeric value.

Having thus described several aspects of at least one example, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

What is claimed is:

1. A system comprising:
a server comprising a computing board and a cooling system,
wherein the computing board comprises a circuit board and a plurality of first processing devices and a plurality of second processing devices attached to the circuit board, wherein each of the first processing devices satisfies one or more first performance criteria at a particular temperature and each of the second processing devices satisfies one or more second performance criteria at the particular temperature; and
wherein the cooling system configured to move a cooling substance from an intake port to a first region in which the first processing devices are attached to the circuit board, from the first region to a second region in which at least a subset of the second processing devices are attached to the circuit board, and from the second region to an exhaust port.

2. The system of claim 1, wherein a first performance level satisfying the first performance criteria is lower than a second performance level satisfying the second performance criteria, and the first performance level does not satisfy the second performance criteria.

3. The system of claim 1, wherein:
the cooling system is operable to cool the first region to a first temperature and the second region to a second temperature higher than the first temperature;
the plurality of first processing devices are configured to perform at a first performance level at the first temperature;
the plurality of second processing devices are configured to perform at a second performance level at the second temperature; and
the first performance level is within a specified range of the second performance level.

4. The system of claim 3, wherein the specified range is 10%, 8%, 6%, 5%, 4%, 3%, or 2%.

5. The system of claim 1, wherein the each of the first processing devices and each of the second processing devices comprises a graphics processing unit (GPU).

6. The system of claim 1, wherein the server is a first server affixed within a server rack comprising a plurality of second servers.

7. The system of claim 1, wherein the plurality of first processing devices and the plurality of second processing devices comprise a combined total of eight processing devices arranged on the circuit board in two rows each comprising four of the eight processing devices, such that a first row of the two rows is within the first region and a second row of the two rows is within the second region.

8. The system of claim 1, wherein the cooling substance comprises ambient air.

9. The system of claim 1, wherein the cooling substance comprises liquid coolant.

10. The system of claim 1, wherein the computing board satisfies a universal baseboard (UBB) design specification.

11. The system of claim 1, wherein the computing board is configured to provide approximately equal amounts of electrical power to each processing device of the first and second pluralities of processing devices.

12. A method of assembling a computing board, the method comprising:
partitioning a set of processing devices into a group of first processing devices and a group of second processing devices based on results of performance testing of the set of processing devices, wherein each of the first processing devices satisfies one or more first performance criteria at a particular temperature and each of the second processing devices satisfies one or more second performance criteria at the particular temperature; and
attaching a plurality of the first processing devices and a plurality of the second processing devices to a circuit board, wherein the attaching includes attaching the plurality of first processing devices to a first area of the circuit board and attaching at least a subset of the plurality of second processing devices to a second area of the circuit board,
wherein the first area of the circuit board is configured to be disposed upstream from the second area of the circuit board along a flow path of a cooling substance of a cooling system.

13. The method of claim 12, further comprising performing the performance testing of the set of processing devices, including:
detecting that fewer than a specified percentage of the set of processing devices satisfy the one or more second performance criteria; and
updating the one or more second performance criteria such that at least the specified percentage of the plurality of processing devices satisfy the updated one or more second performance criteria.

14. The method of claim 12, further comprising performing the performance testing of the set of processing devices, including: for each processing device in the set of processing devices, monitoring a performance of the processing device and a temperature of the processing device while performing at least one processing test.

15. The method of claim 12, further comprising performing the performance testing of the plurality of processing devices, including: for each processing device in the set of processing devices, performing an end-to-end performance test of the processing device.

16. The method of claim 12, wherein:
the cooling system is operable to cool the first area to a first temperature and the second area to a second temperature higher than the first temperature;
the plurality of first processing devices are configured to perform at a first performance level at the first temperature;
the plurality of second processing devices are configured to perform at a second performance level at the second temperature; and
the first performance level is within a specified range of the second performance level.

17. The method of claim 16, wherein the specified range is 10%, 8%, 6%, 5%, 4%, 3%, or 2%.

18. The method of claim 12, wherein the each of the first processing devices and each of the second processing devices comprises a GPU.

19. A computing device comprising:
a circuit board;
a plurality of first processing devices, wherein each of the first processing devices is configured to satisfy one or more first performance criteria at a particular temperature; and
a plurality of second processing devices, wherein each of the second processing devices is configured to satisfy one or more second performance criteria at the particular temperature;
wherein the first processing devices are attached to a first area of the circuit board, at least a subset of the second processing devices are attached to a second area of the circuit board, and the first area of the circuit board is configured to be disposed upstream from the second area of the circuit board along a flow path of a cooling substance of a cooling system.

20. The computing device of claim 19, further comprising the cooling system, wherein the cooling system is configured to move the cooling substance along the flow path from an intake port to the first area of the circuit board, from the first area to the second area of the circuit board, and from the second area to an exhaust port.
